(19) United States
(12) Patent Application Publication
(10) Pub. No.: US 2025/0191947 A1
(43) Pub. Date: Jun. 12, 2025

(54) ARTICLE TRANSPORT FACILITY

(71) Applicant: SEMES CO., LTD., Chungcheongnam-do (KR)

(72) Inventor: Mei Xiang JIN, Gyeonggi-do (KR)

(21) Appl. No.: 18/977,906

(22) Filed: Dec. 11, 2024

(30) Foreign Application Priority Data
Dec. 12, 2023 (KR) 10-2023-0179368

(51) Int. Cl. H01L 21/677

(52) U.S. Cl. CPC H01L 21/67724; H01L 21/67706; H01L 21/67715; H01L 21/67733; H01L 21/67769

(57) ABSTRACT

An article transport system provided in a semiconductor fabricating plant, includes: a rail unit along which a vehicle moves; and a port module including one or more in-ports provided in the rail unit so that an article unloaded from the vehicle is disposed and one or more out-ports provided in the rail unit so that an article loaded to the vehicle is disposed, wherein the in-port is disposed prior to the out-port based on a direction in which the vehicle travels forward.

### CROSS-REFERENCE TO RELATED APPLICATION

This application claims priority from Korean Patent Application No. 10-2023-0179368 filed on Dec. 12, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to an article transport system.

### 2. Description of the Related Art

In order to fabricate semiconductors, various processes should be performed by a substrate processing device. To this end, articles such as wafers should be transported from an arbitrary position to a target position.

In a semiconductor fabricating site such as a clean room, an article transport system including a vehicle such as an overhead hoist transport (OHT) and a rail has been used in order to efficiently transport the article. Here, the vehicle travels along the rail.

In addition, the vehicle performs a loading/unloading operation in order to transport the article, and does not stop at a loading/unloading place and continuously moves like yielding traveling to enable another vehicle disposed behind the vehicle to travel, during a period in which the vehicle does not perform the loading/unloading operation. In addition, since the vehicle travels only forward, when the vehicle fails to perform a loading operation once, the vehicle does not travels backward, such that the vehicle should move a long distance and return.

In addition, a semiconductor fabricating plant are provided with a plurality of fabs, and the article in not transported in only one fab and may be transported between fabs, and the transport of the article between the fabs is performed in an interface zone.

Since a large number of vehicles enter the interface zone like a case where the articles are transported between the plurality of fabs, congestion may occur in the interface zone, such that a transport index may deteriorate. Therefore, structure improvement for operational efficiency is required.

### SUMMARY

Aspects of the present disclosure provide an article transport system in which congestion of vehicles transporting articles in a semiconductor fabricating plant may be reduced or solved.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, an article transport system provided in a semiconductor fabricating plant, includes: a rail unit along which a vehicle moves; and a port module including one or more in-ports provided in the rail unit so that an article unloaded from the vehicle is disposed and one or more out-ports provided in the rail unit so that an article loaded to the vehicle is disposed, wherein the in-port is disposed prior to the out-port based on a direction in which the vehicle travels forward.

According to another aspect of the present disclosure, an article transport system provided in a semiconductor fabricating plant, includes: a rail unit along which a vehicle moves; and a port module including one or more in-ports provided in the rail unit so that an article unloaded from the vehicle is disposed and one or more out-ports provided in the rail unit so that an article loaded to the vehicle is disposed, wherein the vehicle moves forward rather than backward, and transports the article to at least one of a first transport region and a second transport region, the rail unit is provided as an entry lane forming a path along which the vehicle approaches or enters the first transport region or the second transport region in a traveling direction of the vehicle and an exit lane forming a path along which the vehicle becomes distant or exits from the first transport region or the second transport region, and the in-port is not provided in the exit lane and is provided in the entry lane.

According to still another aspect of the present disclosure, an article transport system in which a vehicle transporting an article while moving between a first fab and a second fab in a semiconductor fabricating plant and moving forward rather than backward transports the article, includes: a rail unit including a first rail module provided so that the vehicle moves in the first fab and a second rail module provided so that the vehicle moves in the second fab; a port module including one or more in-ports provided in the rail unit so that the article unloaded from the vehicle is disposed, one or more out-ports provided in the rail unit so that the article loaded to the vehicle is disposed, and conveyors provided at the in-ports and the out-ports and transporting the article; and an interface zone between the first fab and the second fab, wherein the first rail module and the second rail module of the rail unit extend to the interface zone, each of the first rail module and the second rail module is provided as an entry lane along which the vehicle enters the interface zone and an exit lane along which the vehicle exits from the interface zone, an end point of the entry lane forms a starting point of the exit lane so that the entry lane and the exit lane constitute one rail and a ‘U’ shape is formed between the entry lane and the exit lane, such that the entry lane and the exit lane are disposed in parallel with each other, the entry lane has a first rail and a second rail, the exit lane has a third rail and a fourth rail, the in-port is not provided in the exit lane and is provided in the entry lane in the interface zone, and is not provided in the second rail and is provided in the first rail, the out-port is not provided in the entry lane and is provided in the exit lane in the interface zone, and is not provided in the fourth rail and is provided in the third rail, and the in-port disposed in the first rail unit and the out-port disposed in the second rail unit are provided to neighbor to each other, one end of the conveyor faces the in-port disposed in the first rail unit, the other end of the conveyor faces the out-port of the second rail unit, such that the article transported from the first fab to the in-port is transported to the second fab.

Detailed contents of other embodiments are described in a detailed description and are illustrated in the drawings.

In an article transport system according to the present disclosure, inefficient traveling due to traveling in which a vehicle should return to out-ports in a disposition of in-ports and out-ports of which an anteroposterior disposition is irregular may be reduced. Therefore, in a region such as an interface zone where a congestion phenomenon may be severe, congestion of vehicles may be solved, such that an operation delay may be reduced and operation rates of the vehicles may be improved.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a fabricating plant provided with an article transport system according to some exemplary embodiments of the present disclosure;

FIG. 2 is a view illustrating an inner portion of region A of FIG. 1;

FIG. 3 is a view illustrating a first bay of FIG. 2;

FIG. 4 is an enlarged view of region B of FIG. 1;

FIG. 5 is a view illustrating region D of FIG. 4;

FIG. 6 is a view illustrating region E of FIG. 4;

FIG. 7 is a view illustrating region F of FIG. 4;

FIG. 8 is a view illustrating an article transport system according to another exemplary embodiment of the present disclosure;

FIG. 9 is a view illustrating an article transport system according to still another exemplary embodiment of the present disclosure; and

FIG. 10 is a view illustrating an article transport system according to still another exemplary embodiment of the present disclosure.

### DETAILED DESCRIPTION OF THE EMBODIMENTS

Hereinafter, exemplary embodiments of the present disclosure will be described in detail with reference to the accompanying drawings. Advantages and features of the present disclosure and methods for accomplishing these advantages and features will become apparent from exemplary embodiments to be described later in detail with reference to the accompanying drawings. However, the present disclosure is not limited to exemplary embodiments to be disclosed below, and may be implemented in various different forms, these exemplary embodiments will be provided only in order to make the present disclosure complete and allow one of ordinary skill in the art to which the present disclosure pertains to completely recognize the scope of the present disclosure, and the present disclosure will be defined by the scope of the claims. Throughout the specification, the same components will be denoted by the same reference numerals.

The terms as used herein are for describing exemplary embodiments rather than limiting the present disclosure. In the present specification, a singular form includes a plural form unless stated otherwise in the phrase. The terms “comprise” and/or “comprising” as used herein do not exclude the existence or addition of one or more other components, steps, operations, and/or elements in addition to the mentioned components, steps, operations, and/or elements.

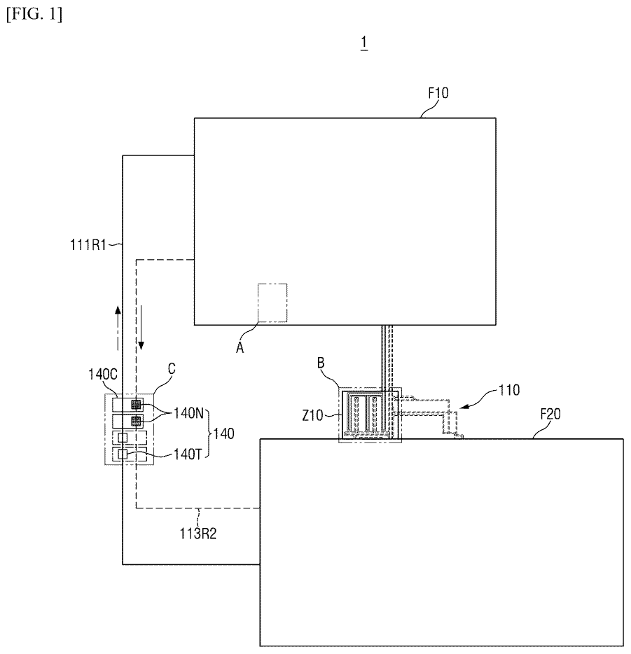

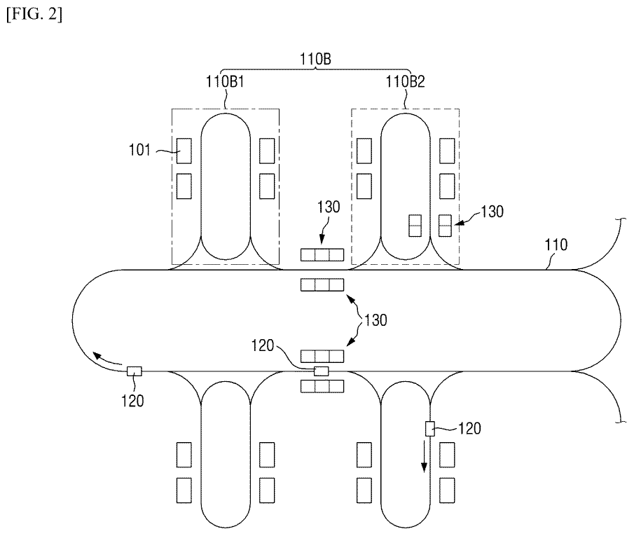

FIG. 1 is a view illustrating a fabricating plant provided with an article transport system according to some exemplary embodiments of the present disclosure, and FIG. 2 is a view illustrating an inner portion of region A of FIG. 1.

Referring to FIGS. 1 and 2, an article transport system according to an exemplary embodiment of the present disclosure may be provided in a fabricating plant 1, and may include a rail unit 110, vehicles 120, article storage units 130, and a port module 140.

In brief, the fabricating plant 1 in which the article transport system is disposed is a semiconductor or display fabricating plant, and may be provided with a plurality of fabrication facilities (fabs) F10 and F20 partitioned into a plurality of spaces/facilities. As an example, it has been illustrated that the plurality of fabs F10 and F20 include a first fab F10 and a second fab F20, but the present disclosure is not limited thereto.

The plurality of fabs F10 and F20 may be provided as clean rooms, and a plurality of substrate processing devices 101 for performing semiconductor fabricating processes may be installed in each of the plurality of fabs F10 and F20. The plurality of substrate processing devices 101 perform a plurality of fabricating processes, such as a depositing process, a lithography process, and an etching process on a substrate (e.g., a wafer).

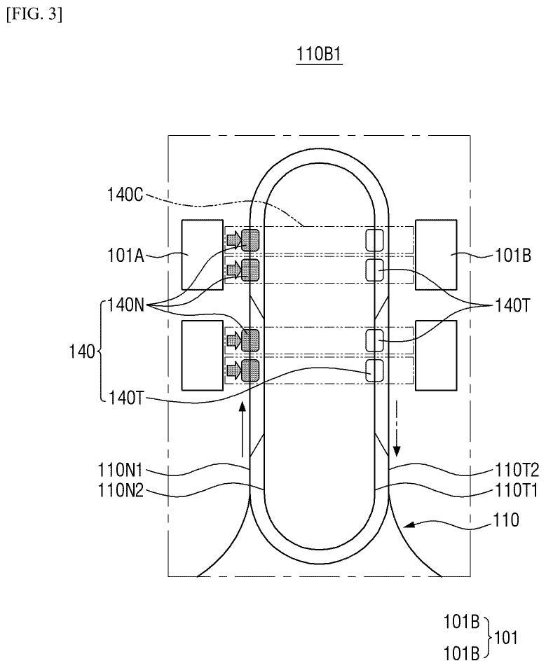

In addition, after a fabricating process is performed in any one semiconductor substrate processing device 101A (see FIG. 3), the substrate may be transported to another semiconductor substrate processing device 101B (see FIG. 3) for the next fabricating process. Here, the substrate may be transported in a state in which it is stored in a container (not illustrated) (e.g., a front opening unified pod (FOUP)) capable of accommodating a plurality of substrates. An article may be transported by the vehicle 120. Hereinafter, the substrate and the container will be referred to as an article.

In order for the article to be transported between the plurality of substrate processing devices 101 or between the plurality of fabs F10 and F20, the rail unit 110 may form a movement path. That is, each of the first fab F10 and the second fab F20 may be provided with the rail unit 110.

The vehicle 120 may move along the movement path formed by the rail unit 110. That is, in the fabricating plant 1 provided with the plurality of fabs F10 and F20, the plurality of substrate processing devices 101 for performing processes may be installed, and a transport path for transporting the article between the substrate processing devices 101 may be formed. The transport path is the movement path of the vehicle 120, and may form an installation path of the rail unit 110. As an example, the rail unit 110 may be provided on the ceiling.

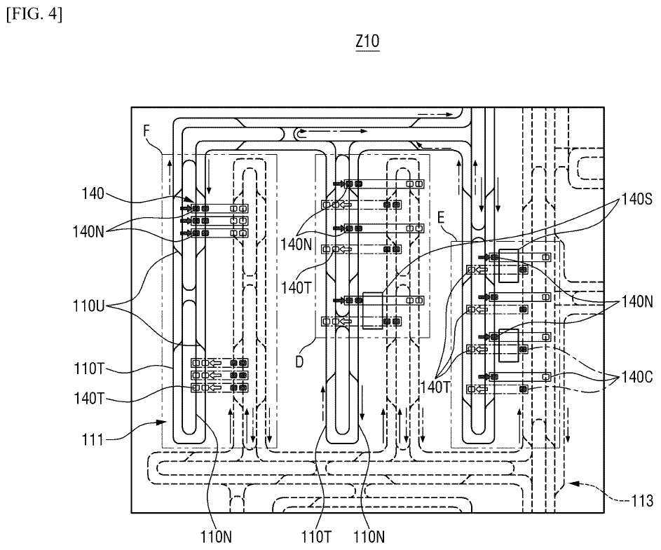

For example, the rail unit 110 provided in each of the first fab F10 and the second fab F20 may have a structure in which straight lines and curved lines are combined with each other. For convenience of explanation, the rail unit 110 provided in the first fab F10 is assumed to be a first rail module 111 (see a solid line in FIG. 4), and the rail unit 110 provided in the second fab F20 is assumed to be a second rail module 113 (see a dotted line in FIG. 4). The first rail module 111 and the second rail module 113 have the same rail structure or similar rail structures, and are different from each other only in that the first rail module 111 is provided in the first fab F10 and the second rail module 113 is provided in the second fab F20.

The rail unit 110 is provided with a plurality of bays 110B where a transport operation is performed for the purpose of utilization of an operation space and easiness of management of the vehicle 120, and the plurality of bays 110B are connected integrally with each other, such that the vehicle 120 does not move only in any one of the plurality of bays 110B and may move to the plurality of bays 110B neighboring to each other.

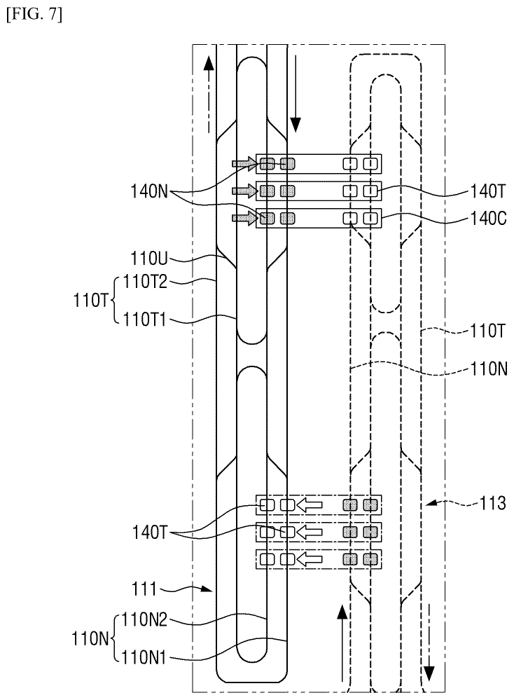

For example, the plurality of bays 110B may have a rail structure of two or more lanes. Here, one lane unit (e.g., a combination of a second rail 110N2 and a third rail 110T1 (see FIGS. 4 and 7)) may have a loop structure, and the other lane unit (e.g., a combination of a first rail 110N1 and a fourth rail 110T2 (see FIGS. 4 and 7)) may have a structure in which it is connected to another bay 110B.

In addition, one lane unit (e.g., the second rail 110N2 and the third rail 110T1) having the loop structure is provided with a structure branching from/joining to the loop structure, such that a plurality of lane units may be connected to each other. For example, the rail unit 110 is provided with detour lines 110U, such that the vehicle 120 may detour and move to neighboring lanes (e.g., the first rail 110N1 and the second rail 110N2 and/or the third rail 110T1 and the fourth rail 110T2).

The rail unit 110 may be provided with a power supply cable (not illustrated) supplying power to the vehicle 120 in a contactless manner (that may be a high-efficiency inductive power distribution (HID) or a contactless power supply (CPS)). The power supply cable may be installed in the entirety or a portion of the rail unit 110.

Such a rail unit 110 may be defined as an entry lane 110N and an exit lane 110T according to lanes along which the vehicle 120 enters or exits from the plurality of fabs F10 and F20 based on the substrate processing device 101, the plurality of fabs F10 and F20, and/or an interface zone Z10.

That is, the first rail module 111 and the second rail module 113 of the rail unit 110 may be provided as the entry lane 110N and the exit lane 110T. A disposition of the port modules 140 may be changed depending on the entry lane 110N and exit lane 110T, which will be described with reference to FIGS. 3 to 10.

Between the first fab F10 and the second fab F20 and/or on sides of the first fab F10 and the second fab F20, the interface zone Z10 may be provided as illustrated in region B of FIG. 1, and bridges 111R1 and 113R2 may be provided as illustrated in region C of FIG. 1.

The interface zone Z10 is a zone between the first fab F10 and the second fab F20, and may be provided with the rail unit 110 for the movement of the vehicle 120. An article transported from the first fab F10 to the second fab F20 or transported from the second fab F20 to the first fab F10 may be loaded/unloaded in the interface zone Z10.

As an example, the substrate may be processed in each of the first fab F10 and the second fab F20, and depending on substrate processing processes, a substrate processing process is performed in the first fab F10, and then, the substrate may be transported to the second fab F20 and the remaining substrate processing process may be performed in the second fab F20. Alternatively, a substrate processing process is performed in the second fab F20, and then, the substrate may be transported to the first fab F10 and the remaining substrate processing process may be performed in the first fab F10. In this case, the article may be transported by the vehicle 120.

That is, a vehicle 120 transporting an article from the first fab F10 may unload the article in the interface zone Z10, load another article transported from the second fab F20, and then move to the first fab F10 again. In addition or separately, a vehicle 120 transporting an article from the second fab F20 may unload the article in the interface zone Z10, load another article transported from the first fab F10, and then move to the second fab F20 again.

As described above, a plurality of vehicles 120 may transport the articles from each of the first fab F10 and the second fab F20 and then perform loading/unloading and transport operations to exchange the articles with each other in the interface zone Z10.

Since such an interface zone Z10 is not provided with the substrate processing device 101, processing of the substrates is not performed and only the exchange of the articles may be performed in the interface zone Z10, such that the interface zone Z10 may be formed to have a smaller space than the fabs F10 and F20. The interface zone Z10 has the smaller space than the fabs F10 and F20 but has a large number of vehicles 120 are disposed in the interface zone Z10, such that a congestion phenomenon of the vehicles 120 may occur in the interface zone Z10. Therefore, in order improve such a problem, in the present exemplary embodiment, the port modules 140 are not disposed randomly and are disposed so that traveling efficiency is improved, which will be described with reference to FIGS. 3 to 10.

The bridges 111R1 and 113R2 may connect the first fab F10 and the second fab F20 to each other, similarly to the interface zone Z10. However, the rail unit 110 of the interface zone Z10 has a ‘U’ shape to form a structure in which the vehicle 120 makes a U-turn, while the rail unit 110 of the bridges 111R1 and 113R2 may form a one-way structure, but the present disclosure is not limited thereto.

In addition, the bridge 111R1 and 113R2 may be provided as the rail unit 110, and may include, for example, an entry bridge 113R2 and an exit bridge 111R1.

That is, the rail unit 110 may be provided as the entry lane 110N and the exit lane 110T, but for the convenience of explanation and understanding, a description will be provided on the assumption that a lane unit (a combination of the entry lane 110N and the exit lane 110T) provided on the sides of the plurality of fabs F10 and F20 is the bridges 111R1 and 113R2.

The entry bridge 113R2 may connect the first rail module 111 and the second rail module 113 to each other, and may form a path along which the vehicle 120 enters the second fab F20 and the second rail module 113 (or the first fab F10 and the first rail module 111) in a direction in which the vehicle 120 travels forward.

In the present exemplary embodiment, the entry bridge 113R2 is defined as a rail along which the vehicle 120 moves toward the second fab F20 based on the second fab F20. In addition, the exit bridge 111R1 is defined as a rail in a direction in which the vehicle 120 exits from the second fab F20 based on the second fab F20.

The entry bridge 113R2 and the entry bridge 113R2 may also be provided with a rail structure along which the vehicle 120 enters or exits from the first fab F10 based on the first fab F10.

In a disposition of the port module 140 according to the present exemplary embodiment, in-ports 140N may be disposed in the entry lane 110N, out-ports 140T may be disposed in the exit lane 110T, and/or the in-ports 140N may be disposed prior to the out-ports 140T, and a disposition of the port module 140 in the interface zone Z10 is the same as or similar to the disposition of the port module 140 in the bridges 111R1 and 113R2.

Accordingly, referring to region C of FIG. 1, it has been illustrated that the out-ports 140T are provided in the exit bridge 111R1 and the in-ports 140N are provided in the entry bridge 113R2, but the present disclosure it is not limited thereto.

That is, it has been assumed in the present exemplary embodiment that each of the entry bridge 113R2 and the exit bridge 111R1 is a one-way rail, but the exit bridge 111R1 is provided similarly to the exit lane 110T and the entry bridge 113R2 is provided similarly to the entry lane 110N, such that each of the exit bridge 111R1 and the entry bridge 113R2 may be provided as two or more rail structures.

In addition, an entry bridge 113R2 and an exit bridge 111R1 may be further provided based on the first fab F10, which are the same as structures of the exit lane 110T and the entry lane 110N and are the same as or similar to a structure of the rail unit 110 inside the interface zone Z10, and an overlapping description is thus omitted.

In addition, although not illustrated in the drawings, each of the plurality of fabs F10 and F20 may be provided as multiple layers, and a tower lift (not illustrated) may be provided so that the vehicle 120 may move to the respective layers. The tower lift may be provided in each of the plurality of fabs F10 and F20.

That is, a first transport region and a second transport region may be provided as the plurality of bays 110B in the tower lift provided for interlayer movement within the plurality of fabs F10 and F20. The tower lift may be provided for the interlayer movement of the vehicle 120, and the substrate processing device 101 may not be provided. A disposition of the port module 140 within the tower lift is the same as or similar to the disposition of the port module 140 within the interface zone Z10, and an overlapping description is thus omitted.

The vehicle 120 may transport the article to the substrate processing device 101, the bridge 111R1 and 113R2, and/or the interface zone Z10 while traveling along the movement path of the rail unit 110. The vehicle 120 moving along the rail unit 110 provided on the ceiling may be provided as an overhead hoist transport (OHT).

As an example, when the vehicle 120 transports the article between the plurality of substrate processing devices 101, the article may be transported directly from any one substrate processing device 101 to another substrate processing device 101 or may be stored in the article storage unit 130 and then transported to another substrate processing device 101 or transported to the port module 140.

The vehicle 120 is not limited to transporting the article between the plurality of substrate processing devices 101, that is, from the plurality of bays 110B, and may also transport the article from each of the plurality of fabs F10 and F20 and transport the article while moving through the interface zone Z10 between the first fab F10 and the second fab F20. In addition, the vehicle 120 may move forward rather than backward for the purpose of operational efficiency, easiness of control, and the like.

Although not illustrated in the drawings, the vehicle 120 may include a gripping unit gripping the article provided as the container and a driving module sliding or raising and lowering the gripping unit. The gripping unit of the vehicle 120 may load/unload the article by sliding in a horizontal direction and then ascending or descending.

The article storage unit 130 may store the article transported by the vehicle 120. The article storage unit 130 may include a rack-type storehouse (e.g., a stocker inside each of the fabs F10 and F20) capable of injecting an inert gas in order to maintain a clean environment within the article provided as the container and an side track buffer (STB) installed adjacent to a side of the rail unit 110 and storing the article or an under track buffer (UTB) installed in a lower region of the rail unit 110 and storing the article. The article storage unit 130 may be installed in a region of the bay 110B or installed in a region outside the bay 110B.

The article storage unit 130 may be installed on the ceiling, identically or similarly to the rail unit 110. The article storage unit 130 may include one or more shelves on which the articles, which are the containers, may be loaded.

Hereinafter, a disposition of the port module 140 of the article transport system will be described with reference to the drawings.

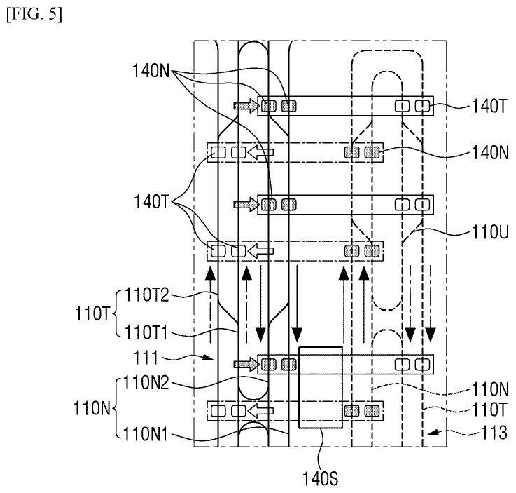

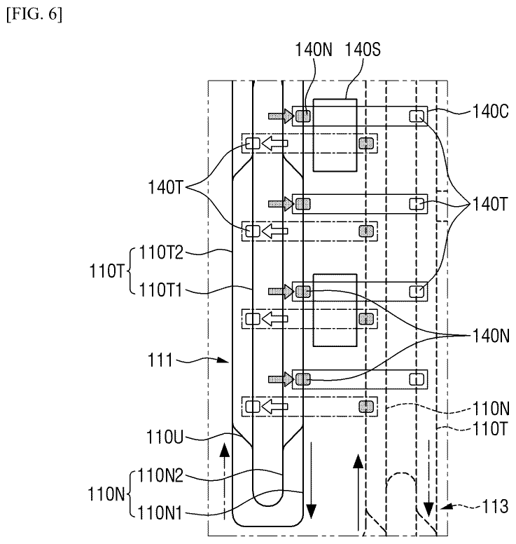

FIG. 3 is a view illustrating a first bay of FIG. 2. FIG. 4 is an enlarged view of region B of FIG. 1, FIG. 5 is a view illustrating region D of FIG. 4, FIG. 6 is a view illustrating region E of FIG. 4, and FIG. 7 is a view illustrating region F of FIG. 4.

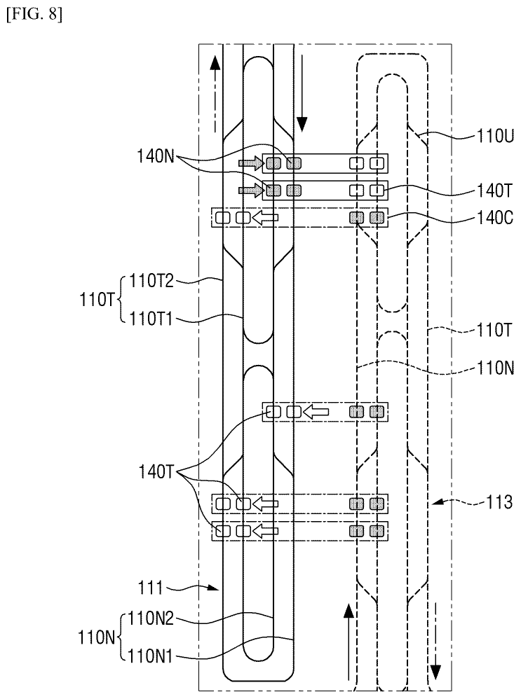

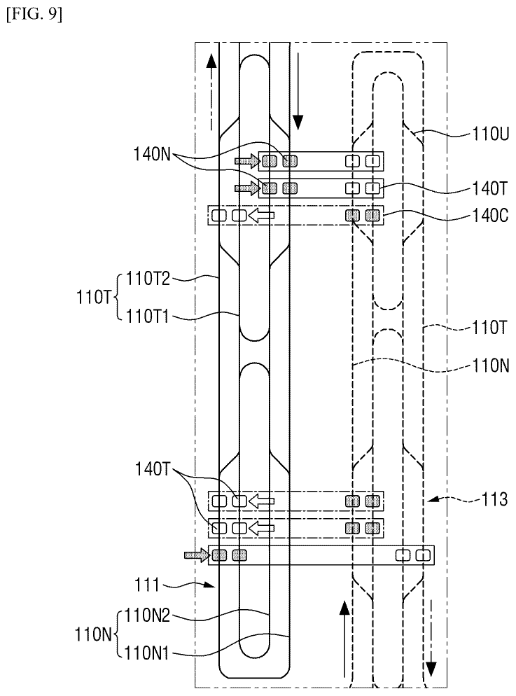

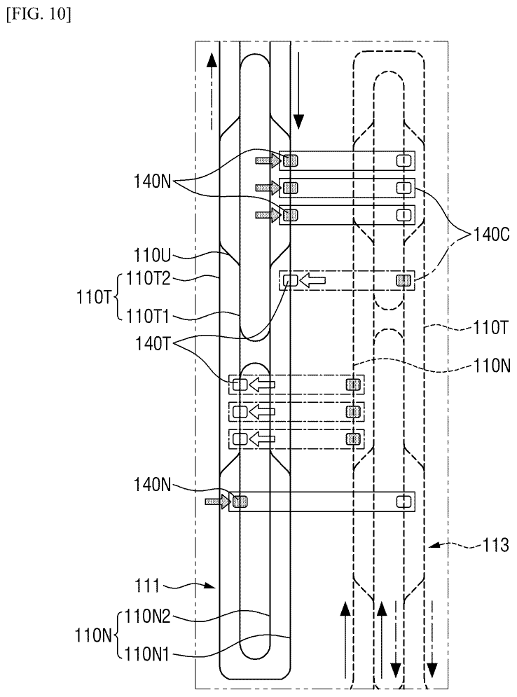

In addition, FIG. 8 is a view illustrating an article transport system according to another exemplary embodiment of the present disclosure, FIG. 9 is a view illustrating an article transport system according to still another exemplary embodiment of the present disclosure, and FIG. 10 is a view illustrating an article transport system according to still another exemplary embodiment of the present disclosure.

Referring to FIGS. 3 to 10, the rail unit 110 of the article transport system may be provided as the entry lane 110N and the exit lane 110T, and the port module 140 may include the in-ports 140N and the out-ports 140T.

Prior to describing the rail unit 110 and the port module 140, the first transport region and the second transport region will first be described below.

The first transport region is assumed to be the first fab F10 based on the plurality of fabs F10 and F20 and is assumed to be a first substrate processing device 101A based on the bay 110B inside one of the fabs F10 and F20. In addition, the second transport region is assumed to be the second fab F20 based on the plurality of fabs F10 and F20 and is assumed to be a second substrate processing device 101B based on the bay 110B inside one of the fabs F10 and F20. Alternatively, based on the plurality of bays 110B, the first transport region may be assumed to be a first bay 110B1 and the second transport region may be assumed to be a second bay 110B2. That is, the first transport region and the second transport region may refer to regions where the articles are exchanged.

The entry lane 110N according to the present exemplary embodiment may form a path along which the vehicle 120 approaches/enters each of the first transport region and the second transport region in the direction in which the vehicle 120 travels forward. That is, based on the interface zone Z10, the entry lane 110N may be defined as a rail along which the vehicle enters the interface zone Z10. For example, based on the first rail module 111 of the interface zone Z10, the entry lane 110N may form a path along which the vehicle 120 approaches the second fab F20 in order to transport the article to the second fab F20. Meanwhile, based on the second rail module 113, the entry lane 110N may form a path along which the vehicle 120 approaches the first fab F10.

Such an entry lane 110N may be provided as a rail along which the vehicle 120 unloads the article so as to transport the article to neighboring transport regions (the first fab F10 and the second fab F20) for exchange of the article, and may be provided with the in-ports 140N. However, the present disclosure is not limited thereto, and according to a modified example of an exemplary embodiment, the entry lane 110N may also be provided with the out-ports 140T.

In addition, referring to FIG. 3, the entry lane 110N may be defined as a path along which the vehicle 120 approaches the first substrate processing device 101A based on the first substrate processing device 101A of the plurality of substrate processing devices 101 in the first bay 110B1 inside the first fab F10.

The exit lane 110T may form a path along which the vehicle 120 is spaced apart/exits from each of the first transport region and the second transport region in the direction in which the vehicle 120 travels forward. That is, based on the interface zone Z10, the exit lane 110T may be defined as a rail along the vehicle 120 exits from the interface zone Z10. For example, based on the first rail module 111 of the interface zone Z10, the exit lane 110T may form a path along which the vehicle 120 becomes distant from the second fab F20 and approaches the first fab F10 so as to load the article transported from the second fab F20 and return from the interface zone Z10 to the first fab F10. Meanwhile, based on the second rail module 113 of the interface zone Z10, the exit lane 110T may form a path along which the vehicle 120 becomes distant from the first fab F10 and approaches the second fab F20.

The exit lane 110T is provided as a rail along which the vehicle 120 loads the article unloaded from the neighboring transport regions (the first fab F10 and the second fab F20) and moves, and may be provided with the out-ports 140T. However, the present disclosure is not limited thereto, and according to a modified example of an exemplary embodiment, the exit lane 110T may be provided with the in-ports 140N or may be provided as a rail in which both the in-ports 140N and the out-ports 140T do not exist.

Each of the entry lane 110N and the exit lane 110T according to the present exemplary embodiments may be provided as a plurality of rails. For example, the entry lane 110N may include the first rail 110N1 and the second rail 110N2, and the exit lane 110T may be provided with the third rail 110T1 and the fourth rail 110T2.

In general, the vehicle 120 performs an unloading operation and then performs a loading operation for a loading/unloading operation. However, the vehicle 120 does not stop at a loading/unloading place and continuously moves as an operation such as yielding traveling, after it performs loading/unloading. In addition, although not illustrated in the drawings, when the out-ports for the loading operation are disposed prior to the in-ports unlike the present exemplary embodiments, the vehicle 120 should first perform the unloading operation at the in-port and then move to an out-port position for the loading operation. However, the vehicle does not travel backward, and should thus return to the out-port position along a long movement distance, such that there is a risk that traveling efficiency will be reduced. Accordingly, unlike the present exemplary embodiments, inefficient traveling such as unnecessary traveling of the vehicle, that is, traveling in which the vehicle should return to the out-port position may occur, such that the number of vehicles entering the interface zone Z10 may increase and congestion may occur, which may cause deterioration of a transport index.

In order to prevent such a problem, in the present exemplary embodiment, the in-ports 140N and the out-ports 140T need to be efficiently disposed, such that the port module 140 is disposed as follows.

First, referring to FIG. 3, in the first bay 110B1 inside the plurality of fabs F10 and F20 (e.g., the first fab F10), the port module 140 may be disposed so that operational efficiency of the vehicle 120 is improved.

Here, the first bay 110B1 within the plurality of fabs F10 and F20 may be provided with the plurality of substrate processing devices 101 unlike the interface zone Z10. The rail unit 110 may be provided with the in-ports 140N and the out-ports 140T so that the article transported from the substrate processing device 101 is loaded/unloaded.

For example, based on the first substrate processing device 101A, the in-ports 140N may be provided in the first rail 110N1 of the entry lane 110N, which is the path along which the vehicle 120 approaches the first substrate processing device 101A. Here, the in-ports 140N may not be provided in the second rail 110N2 of the entry lane 110N. This is to prevent a vehicle 120 that does not load/unload the article from being congested with a vehicle 120 that loads/unloads the article, that is, to enable high-speed traveling in which the vehicle 120 continuously travels without stopping.

In addition, the out-ports 140T may not be provided in the entry lane 110N and may be provided in the exit lane 110T, and may not be provided in the fourth rail 110T2 of the exit lane 110T and may be provided in the third rail 110T1 of the exit lane 110T. This is for the purpose of high-speed traveling of the vehicle 120.

The disposition of the in-ports 140N and the out-ports 140T according to the present exemplary embodiment in one first bay 110B1 has been illustrated, but this is assumed for the convenience of explanation, and a structure for transporting the article may also be formed between the first bay 110B1 and the second bay 110B2. In addition, a disposition of the port module 140 of the first bay 110B1 is the same as or similar to a disposition structure of the port module 140 in the exit lane 110T and the entry lane 110N of the rail unit 110 in the interface zone Z10, and an overlapping description is thus omitted.

Hereinafter, the port module 140 of the interface zone Z10 will be described.

Referring to FIGS. 4 to 10, the rail unit 110 in which the port module 140 is disposed may be provided so that the vehicle 120 may load/unload the article inside the interface zone Z10 in order to transport the article from the first fab F10 to the second fab F20. In addition, the rail unit 110 may be provided so that the vehicle 120 may load/unload the article inside the interface zone Z10 in order to transport the article from the second fab F20 to the first fab F10.

A transport path of the rail unit 110 may have a structure in which the vehicle 120 makes a U-turn. In the U-turn structure of the rail unit 110, one end or the other end of the rail unit 110 may have a U-turn structure or both ends of the rail unit 110 may have a U-turn structure. That is, the bay 110B of the rail unit 110 is not limited to being provided in the plurality of fabs F10 and F20, and may be provided identically or similarly inside the interface zone Z10.

Accordingly, in the rail unit 110, an end point of the entry lane 110N may form a starting point of the exit lane 110T so that the entry lane 110N and the exit lane 110T constitute one rail, and a ‘U’ shape may be formed between the entry lane 110N and the exit lane 110T, such that the entry lane 110N and the exit lane 110T may be disposed in parallel with each other. In addition, the detour lines 110U may be provided.

In addition, the port module 140 may be provided with the in-ports 140N, the out-ports 140T, and conveyors 140C.

One or more in-ports 140N may be provided in the rail unit 110. The article unloaded from the vehicle 120 may be disposed in the in-port 140N. One or more out-ports 140T may be provided in the rail unit 110. The article loaded to the vehicle 120 may be disposed in the out-port 140T.

Each of the in-ports 140N and the out-ports 140T may be positioned below the vehicle 120 on the movement path of the vehicle 120, but is not limited thereto. In addition, the conveyors 140C may be provided at the in-ports 140N and the out-ports 140T, and the articles may be moved by the conveyors 140C, but the present disclosure is not limited thereto.

The conveyor 140C may move the article to be unloaded from the vehicle 120 or loaded to the vehicle 120. One end of the conveyor 140C may form the in-port 140N and the other end of the conveyor 140C may form the out-port 140T, but this is only an example.

For example, the in-port 140N of the first fab F10 may form a unit with the out-port 140T of the second fab F20, such that an article unloaded from the in-port 140N of the first fab F10 by the vehicle 120 may be moved to the out-port 140T of the second fab F20 by the conveyor 140C and an article on the out-port 140T of the second fab F20 may be loaded and transported by the vehicle 120 moving in the second fab F20.

That is, the conveyor 140C may move the article between the in-port 140N of the first fab F10 and the out-port 140T of the second fab or move between the in-port 140N of the second fab F20 and the out-port 140T of the first fab F10. Accordingly, the vehicle 120 may transport/exchange the article without directly moving from the first fab F10 to the second fab and without directly moving from the second fab F20 to the first fab F10. Here, arrows, in left and right directions, of the conveyors 140C illustrated in FIGS. 4 to 9 refer to moving directions of the conveyors 140C.

In addition, the port module 140 may be further provided with stockers 140S. The stocker 140S may be provided between the in-port 140N and the out-port 140T so that the conveyor 140C penetrates through the stocker 140S, and the article may be temporarily stored in the stocker 140S. In addition, various modified examples such as a modified example in which the stocker 140S may be provided with a transport robot (not illustrated), such that that interlayer movement of the article is possible in the stocker 140S are possible.

The in-ports 140N will be described again. The in-ports 140N may be positioned prior to the out-ports 140T based on a traveling direction of the vehicle 120. For example, the exit lane 110T is provided as one rail following the entry lane 110N, the in-ports 140N may be disposed prior to the out-ports 140T in the entry lane 110N and may be larger in number than the out-ports 140T.

According to an exemplary embodiment, the in-ports 140N may not be provided in the exit lane 110T and may be provided in the entry lane 110N, in the interface zone Z10. The out-ports 140T may be provided in the entry lane 110N or the exit lane 110T in the interface zone Z10. According to a modified example of an exemplary embodiment, the out-ports 140T may be provided only in the entry lane 110N, and may be larger in number than the in-ports 140N in the entry lane 110N.

First, referring to FIG. 5 (region D of FIG. 4), the in-ports 140N may be provided in the entry lane 110N and provided in each of the first rail 110N1 and the second rail 110N2. The out-ports 140T may not be provided in the entry lane 110N, and may be provided in the exit lane 110T and provided in each of the third rail 110T1 and the fourth rail 110T2.

Accordingly, the vehicle 120 may unload the article loaded from the first fab F10, load the article transported from the second fab F20 and then move, such that operational efficiency may be improved. In other words, the vehicle 120 that travels forward rather than backward performs an unloading operation at the in-ports 140N and then a loading operation at the out-ports 140T. Accordingly, the vehicle 120 according to the present exemplary embodiment may pass through the in-ports 140N and pass through the out-ports 140T. Therefore, the vehicle 120 may not perform traveling in which the vehicle 120 returns to the out-ports 140T disposed prior to the in-ports 140N, which is performed when the out-ports 140T and the in-ports 140N are randomly disposed as in the related art, such that the operational efficiency of the vehicle 120 may be improved.

Referring to FIG. 6 (region E of FIG. 4), the in-ports 140N may be provided in the entry lane 110N, and may not be provided in the second rail 110N2 and may be provided in the first rail 110N1 so that the vehicle 120 may travel at a high speed (the vehicle 120 may travel without stopping) without performing a loading/unloading operation in the second rail 110N2. In addition, the out-ports 140T may not be provided in the entry lane 110N and may be provided in the exit lane 110T, and may not be provided in the fourth rail 110T2 and may be provided in the third rail 110T1 so that the vehicle 120 may travel at a high speed without performing a loading/unloading operation in the fourth rail 110T2.

Accordingly, a vehicle 120 that has first performed a loading/unloading operation but is put in a lower priority may avoid a vehicle 120 that is performing a loading/unloading operation to move to the second rail 110N2/fourth rail 110T2 in which the in-ports 140N and the out-ports 140T do not exist through the detour line 110U, and thus, the vehicle 120 may travel at a high speed, such that the traveling efficiency of the vehicle 120 may be further improved.

In addition, according to a modified example of an exemplary embodiment, various modified examples such as a modified example in which the vehicle 120 waits in the detour line 110U and the vehicle 120 loads the article coming out from the out-port 140T and exits from the interface zone Z10 are possible.

Referring to FIG. 7 (region F of FIG. 4), each of the in-ports 140N and the out-ports 140T is not provided in the exit lane 110T and is provided in the entry lane 110N, such that the vehicle 120 may travel at a high speed without performing the loading/unloading operation in the exit lane 110T. For example, each of the in-ports 140N and the out-ports 140T may be provided in each of the first rail 110N1 and the second rail 110N2. Alternatively, various modified examples such as a modified example in which the in-ports 140N and the out-ports 140T are provided in either the first rail 110N1 or the second rail 110N2 or the in-ports 140N are provided in the first rail 110N1 and the out-ports 140T are provided in the second rail 110N2 are possible.

Referring to FIG. 8, the in-ports 140N may not be provided in the exit lane 110T and may be provided in the entry lane 110N. The out-ports 140T may be disposed posterior to the in-ports 140N with respect to the traveling direction of the vehicle 120, and may be provided in one or more of the first rail 110N1, the second rail 110N2, the third rail 110T1, and the fourth rail 110T2. For example, the out-ports 140T may be provided in all of the first rail 110N1, the second rail 110N2, the third rail 110T1, and the fourth rail 110T2, but are not limited thereto.

As another example, referring to FIG. 9, the in-ports 140N may be provided in both the entry lane 110N and the exit lane 110T, and may be provided in the first rail 110N1, the second rail 110N2, the third rail 110T1, and/or the fourth rail 110T2. The out-ports 140T may be disposed posterior to the in-ports 140N with respect to the traveling direction of the vehicle 120, and may not be provided in the entry lane 110N and may be provided in the exit lane 110T and provided in each of the third rail 110T1 and/or the fourth rail 110T2.

Alternatively, both the in-ports 140N and the out-ports 140T are not disposed in at least one of the first rail 110N1, the second rail 110N2, the third rail 110T1, and the fourth rail 110T2, such that at least one of the first rail 110N1, the second rail 110N2, the third rail 110T1, and the fourth rail 110T2 may be implemented so that high-speed traveling of the vehicle 120 is performed.

As still another example, referring to FIG. 10, based on the first rail module 111, the in-ports 140N may be provided in both the entry lane 110N and the exit lane 110T, and may be larger in number than the out-ports 140T in the entry lane 110N and smaller in number than the out-ports 140T in the exit lane 110T.

For example, both the in-ports 140N and the out-port 140T may be provided in the first rail 110N1 of the entry lane 110N, and three in-ports 140N may be provided and disposed prior to the out-port 140T in the first rail 110N1. In addition, both the in-port 140N and the out-ports 140T may be provided in the third rail 110T1 of the exit lane 110T, and one in-port 140N may be provided and disposed prior to the out-ports 140T in the third rail 110T1. In this case, in the third rail 110T1, the number of out-ports 140T may be larger than the number of in-ports 140N. For example, three out-ports 140T may be provided in the third rail 110T1.

Here, both the in-ports 140N and the out-port 140T may not be provided in the second rail 110N2 of the entry lane 110N and the fourth rail 110T2 of the exit lane 110T, such that that the vehicle 120 may travel at a high speed in the second rail 110N2 of the entry lane 110N and the fourth rail 110T2 of the exit lane 110T.

In addition, the first rail module 111 may be provided with the detour line 110U, such that the vehicle 120 that is traveling may travel while detouring the vehicle 120 that has stopped for the loading/unloading operation.

As still another example, referring to FIG. 10, based on the second rail module 113, the entry lane 110N may be provided with only the in-ports 140N and may not be provided with the out-ports 140T, and the exit lane 110T connected to the entry lane 110N may be provided with both the in-ports 140N and the out-ports 140T. In this case, in the exit lane 110T, the number of out-ports 140T may be larger than the number of in-ports 140N.

In the article transport system according to such exemplary embodiments, inefficient traveling due to traveling in which the vehicle 120 should return to the out-ports in a disposition of the in-ports and the out-ports of which an anteroposterior disposition is irregular in order to perform the loading operation after the unloading operation may be reduced. Therefore, in a region such as the interface zone Z10 where a congestion phenomenon may be severe, congestion of the vehicles 120 may be solved, such that an operation delay may be reduced and operation rates of the vehicles may be improved.

The exemplary embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the exemplary embodiments described above are illustrative rather than being restrictive in all aspects.

What is claimed is:

1. An article transport system provided in a semiconductor fabricating plant, comprising:
a rail unit along which a vehicle moves; and
a port module including one or more in-ports provided in the rail unit so that an article unloaded from the vehicle is disposed and one or more out-ports provided in the rail unit so that an article loaded to the vehicle is disposed,
wherein the in-port is disposed prior to the out-port based on a direction in which the vehicle travels forward.

2. The article transport system of claim 1, wherein the vehicle moves forward rather than backward, and transports the article to at least one of a first transport region and a second transport region constituting a region where the article is transported, and
the rail unit is provided as an entry lane forming a path along which the vehicle approaches or enters at least one of the first transport region or the second transport region in the direction in which the vehicle travels forward and an exit lane forming a path along which the vehicle becomes distant or exits from at least one of the first transport region or the second transport region in the direction in which the vehicle travels forward.

3. The article transport system of claim 2, wherein an end point of the entry lane forms a starting point of the exit lane so that the entry lane and the exit lane constitute one rail, and
a ‘U’ shape is formed between the entry lane and the exit lane, such that the entry lane and the exit lane are disposed in parallel with each other.

4. The article transport system of claim 2, wherein the in-port is not provided in the exit lane and is provided in the entry lane.

5. The article transport system of claim 4, wherein in the entry lane, the number of in-ports is larger than the number of out-ports.

6. The article transport system of claim 4, wherein the rail unit includes a first rail and a second rail constituting the entry lane, and
the in-port is not provided in the second rail and is provided in the first rail.

7. The article transport system of claim 2, wherein the out-port is not provided in the entry lane and is provided in the exit lane.

8. The article transport system of claim 7, wherein in the exit lane, the number of out-ports is larger than the number of in-ports.

9. The article transport system of claim 7, wherein the rail unit includes a third rail and a fourth rail constituting the exit lane, and
the out-port is not provided in the fourth rail and is provided in the third rail.

10. The article transport system of claim 2, wherein the first transport region is provided as a first fab,
the second transport region is provided as a second fab neighboring to the first fab, and
the rail unit includes:
a first rail module provided so that the vehicle moves in the first fab; and
a second rail module provided so that the vehicle moves in the second fab.

11. The article transport system of claim 10, wherein the first rail module and the second rail module extend to an interface zone between the first fab and the second fab, and
the in-port is disposed prior to the out-port in the interface zone.

12. The article transport system of claim 2, wherein the first transport region is provided as a first substrate processing device processing a substrate or a first bay of the rail unit in which the first substrate processing device is provided or is not provided and which forms an interlayer movement section,
the second transport region is provided as a second substrate processing device processing the substrate and neighboring to the first substrate processing device or a second bay of the rain unit neighboring to the first bay, and
the in-port is disposed prior to the out-port in the first bay or is disposed in prior to the out-port in a first fab where the first bay and the second bay are provided.

13. The article transport system of claim 2, wherein the in-port and the out-port are not provided in the exit lane and are provided in the entry lane, and
a plurality of in-ports are disposed prior to the out-port in the entry lane, and a plurality of out-ports are disposed posterior to the in-ports in the entry lane.

14. The article transport system of claim 1, wherein the port module includes a conveyor moving the article in the in-port and the out-port.

15. An article transport system provided in a semiconductor fabricating plant, comprising:
a rail unit along which a vehicle moves; and
a port module including one or more in-ports provided in the rail unit so that an article unloaded from the vehicle is disposed and one or more out-ports provided in the rail unit so that an article loaded to the vehicle is disposed,
wherein the vehicle moves forward rather than backward, and transports the article to at least one of a first transport region and a second transport region,
the rail unit is provided as an entry lane forming a path along which the vehicle approaches or enters the first transport region or the second transport region in a traveling direction of the vehicle and an exit lane forming a path along which the vehicle becomes distant or exits from the first transport region or the second transport region, and
the in-port is not provided in the exit lane and is provided in the entry lane.

16. The article transport system of claim 15, wherein the rail unit includes a first rail and a second rail constituting the entry lane and a third rail and a fourth rail constituting the exit lane, and
the in-port is not provided in the second rail and is provided in the first rail, and
the out-port is not provided in the entry lane and is provided in the exit lane, and is not provided in the fourth rail and is provided in the third rail.

17. The article transport system of claim 15, wherein the first transport region is provided as a first fab,
the second transport region is provided as a second fab neighboring to the first fab,
the rail unit includes:
a first rail module disposed so that the vehicle moves in the first fab and provided with the entry lane and the exit lane; and
a second rail module disposed so that the vehicle moves in the second fab and provided with the entry lane and the exit lane,
the first rail module and the second rail module extend to an interface zone between the first fab and the second fab,
an end point of the entry lane forms a starting point of the exit lane so that the entry lane and the exit lane of each of the first rail module and the second rail module constitute one rail, and
a ‘U’ shape is formed between the entry lane and the exit lane, such that the entry lane and the exit lane are disposed in parallel with each other.

18. The article transport system of claim 17, wherein the rail unit includes:
an entry bridge spaced apart from the interface zone outside each of the first fab and the second fab, connecting the first rail module and the second rail module to each other, and forming a path along which the vehicle enters the first rail module or the second rail module in a direction in which the vehicle travels forward; and
an exit bridge spaced apart from the interface zone outside each of the first fab and the second fab, connecting the first rail module and the second rail module to each other, and forming a path along which the vehicle exits from the second rail module or the first rail module in the direction in which the vehicle travels forward, and
the in-port is not provided in the exit bridge and is provided in the entry bridge.

19. An article transport system in which a vehicle transporting an article while moving between a first fab and a second fab in a semiconductor fabricating plant and moving forward rather than backward transports the article, comprising:
a rail unit including a first rail module provided so that the vehicle moves in the first fab and a second rail module provided so that the vehicle moves in the second fab;
a port module including one or more in-ports provided in the rail unit so that the article unloaded from the vehicle is disposed, one or more out-ports provided in the rail unit so that the article loaded to the vehicle is disposed, and conveyors provided at the in-ports and the out-ports and transporting the article; and
an interface zone between the first fab and the second fab,
wherein the first rail module and the second rail module of the rail unit extend to the interface zone,
each of the first rail module and the second rail module is provided as an entry lane along which the vehicle enters the interface zone and an exit lane along which the vehicle exits from the interface zone,
an end point of the entry lane forms a starting point of the exit lane so that the entry lane and the exit lane constitute one rail and a ‘U’ shape is formed between the entry lane and the exit lane, such that the entry lane and the exit lane are disposed in parallel with each other,
the entry lane has a first rail and a second rail,
the exit lane has a third rail and a fourth rail,
the in-port is not provided in the exit lane and is provided in the entry lane in the interface zone, and is not provided in the second rail and is provided in the first rail,
the out-port is not provided in the entry lane and is provided in the exit lane in the interface zone, and is not provided in the fourth rail and is provided in the third rail, and
the in-port disposed in the first rail unit and the out-port disposed in the second rail unit are provided to neighbor to each other, one end of the conveyor faces the in-port disposed in the first rail unit, the other end of the conveyor faces the out-port of the second rail unit, such that the article transported from the first fab to the in-port is transported to the second fab.
